(19) United States
(12) Patent Application Publication
(10) Pub. No.: US 2026/0238246 A1
(43) Pub. Date: Aug. 13, 2026

(54) Multi-phase Subsampling Mixer

(71) Applicant: Apple Inc., Cupertino, CA (US)

(72) Inventors: Ankit Srivastava, San Diego, CA (US); Morteza Nick, San Diego, CA (US)

(21) Appl. No.: 19/051,829

(22) Filed: Feb. 12, 2025

(51) Int. Cl. H04B 1/40; H03L 7/099; H04B 1/00

(52) U.S. Cl. CPC H04B 1/40; H03L 7/099; H04B 1/0078

(57) ABSTRACT

Wireless circuitry may include a radio-frequency mixer. The mixer can include an input terminal configured to receive a radio-frequency signal, an output terminal on which a corresponding downconverted signal is produced, and multiple subsampling circuits coupled in parallel between the input terminal and the output terminal. An associated clock generator can be configured to output multiple clock signals for controlling the subsampling circuits. The radio-frequency signal can have a first frequency, and the clock signals can each have a second frequency that is a fraction of the first frequency. Each of the subsampling circuits can include a storage capacitor and associated switches.

### FIELD

This disclosure relates generally to electronic devices, including electronic devices with wireless communications circuitry.

### BACKGROUND

Electronic devices are often provided with wireless communications capabilities. An electronic device with wireless communications capabilities has wireless communications circuitry with one or more antennas. Transceiver circuitry in the wireless communications circuitry uses the antennas to receive and transmit radio-frequency signals.

The transceiver circuitry can include one or more mixers for modulating or demodulating the radio-frequency signals. The mixers can receive an oscillating signal from a phase-locked loop. It can be challenging to design a satisfactory mixer for the wireless communications circuitry.

### SUMMARY

An aspect of the disclosure provides radio-frequency mixer circuitry that includes an input terminal configured to receive a radio-frequency signal, an output terminal on which a corresponding downconverted signal is produced, and a plurality of subsampling circuits, where each subsampling circuit in the plurality of subsampling circuits is coupled between the input terminal and the output terminal. The mixer circuitry can further include a clock generator configured to output a plurality of clock signals for controlling the plurality of subsampling circuits. The radio-frequency signal has a first frequency, and the plurality of clock signals can have a second frequency that is less than the first frequency. A first subsampling circuit in the plurality of subsampling circuits can be controlled by at least a first clock signal of a first phase in the plurality of clock signals, whereas a second subsampling circuit in the plurality of subsampling circuits can be controlled by at least a second clock signal of a second phase, different than the first phase, in the plurality of clock signals.

An aspect of the disclosure provides a method of operating a mixer that includes receiving a radio-frequency signal with a first sampling circuit, receiving the radio-frequency signal with a second sampling circuit coupled in parallel with the first sampling circuit, controlling the first sampling circuit with a first clock phase, and controlling the second sampling circuit with a second clock phase that is delayed with respect to the first clock phase. The method can further include receiving the radio-frequency signal with a third sampling circuit coupled in parallel with the first and second sampling circuits, and controlling the third sampling circuit with a third clock phase that is delayed with respect to the second clock phase. The radio-frequency signal has a first frequency, and the first and second clock phases can each have a second frequency that is a fraction of the first frequency.

An aspect of the disclosure provides mixer circuitry that includes an input terminal configured to receive a radio-frequency signal, an output terminal on which a corresponding downconverted signal is produced, and a plurality of sampling circuits coupled in parallel between the input terminal and the output terminal and configured to boost a signal level of the radio-frequency signal. The radio-frequency signal has a first frequency. A first sampling circuit in the plurality of sampling circuits can be controlled by a first pair of clock phases having a second frequency that is a fraction of the first frequency. A second sampling circuit in the plurality of sampling circuits can be controlled by a second pair of clock phases, different than the first pair of clock phases, having the second frequency. A third sampling circuit in the plurality of sampling circuits can be controlled by a third pair of clock phases, different than the first and second pairs of clock phases, having the second frequency.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having a transceiver in accordance with some embodiments.

FIG. 3 is circuit diagram of illustrative multi-phase subsampling mixer circuitry in accordance with some embodiments.

FIG. 4 is a timing diagram illustrating how a radio-frequency signal can be subsampled using multiple clock phases in accordance with some embodiments.

FIG. 5 is a plot of gain versus frequency showing how multi-phase sampling can exhibit improved blocker rejection over single-phase sampling in accordance with some embodiments.

FIG. 6 is a circuit diagram of illustrative multi-phase subsampling mixer circuitry with signal boosting capabilities in accordance with some embodiments.

### DETAILED DESCRIPTION

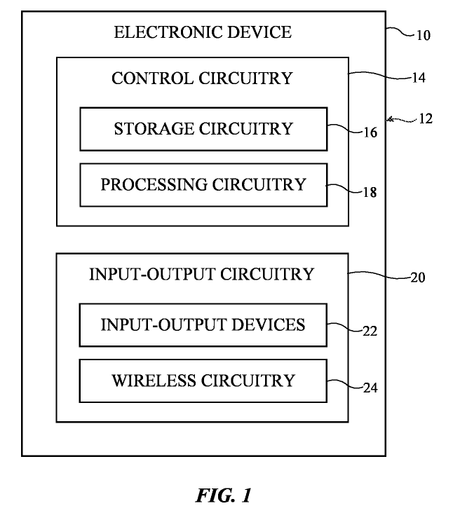

An electronic device such as electronic device 10 of FIG. 1 may be provided with wireless circuitry. The wireless circuitry may include a multi-phase subsampling mixer for downconverting a radio-frequency signal having frequency f RF. The multi-phase subsampling mixer can include N subsampling circuits, where each of the subsampling circuits includes one or more capacitors and one or more associated switches. In general, N can be an integer that is greater than 2, greater than 5, greater than 10, 10-20, 20-50, 50-100, or greater than 100. The N subsampling circuits can be controlled by N respective phases of a low-frequency clock signal to sample the incoming radio-frequency signal. The low-frequency clock signal can have a sampling frequency f S that is equal to f RF divided by N. The N clock phases can be generated using a delay-locked loop (DLL), a multiplier DLL, or other clock generation circuit. A multi-phase subsampling mixer configured and operated in this way may be technically advantageous and beneficial to provide improved interference (aliasing) tolerance with lower power consumption compared to mixers that use phase-locked loops (PLLs). The N subsampling circuits can optionally provide signal boosting to further improve the noise figure of the wireless circuitry.

Electronic device 10 of FIG. 1 that includes a multi-phase subsampling mixer may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user’s head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols – sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio-frequency signal transmission and/or reception for device 10. Wireless circuitry 24 may be used for wireless communications. Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

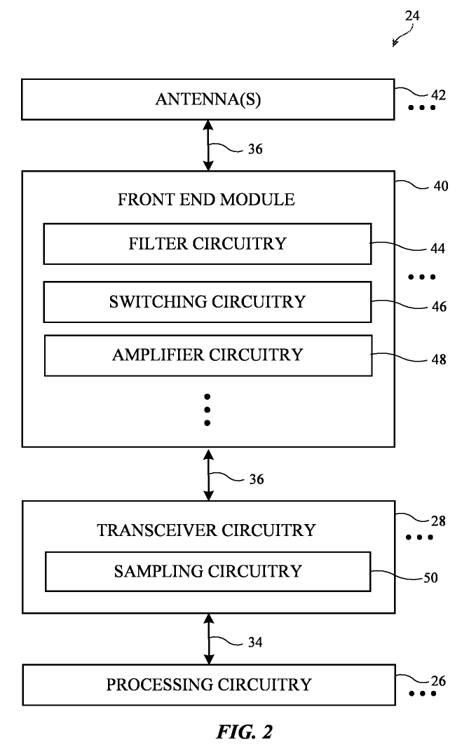

FIG. 2 is a diagram showing illustrative components within wireless circuitry 24. As shown in FIG. 2, wireless circuitry 24 may include processing circuitry such as processor circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be a baseband processor, an application processor, a digital signal processor, a microcontroller, a microprocessor, a central processing unit (CPU), a programmable device, a combination of these circuits, and/or one or more processors within circuitry 18. Processing circuitry 26 may be configured to generate digital (transmit or baseband) signals. Processing circuitry 26 may be coupled to transceiver 28 over path 34 (sometimes referred to as a baseband path). Transceiver 28 may be coupled to antenna 42 via radio-frequency transmission line path 36. Radio-frequency front-end module 40 may be interposed on radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit configured to output uplink signals to antenna 42, may include a receiver circuit configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module interposed thereon.

Front-end module (FEM) 40 may include radio-frequency front-end circuitry that operates on the radio-frequency signals conveyed (transmitted and/or received) over radio-frequency transmission line path 36. Front-end module may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and one or more low-noise amplifiers), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be interposed within radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

In performing wireless transmission, processing circuitry 26 may provide digital baseband signals to transceiver 28 over path 34. Transceiver 28 may further include circuitry for converting the baseband signals received from processing circuitry 26 into corresponding intermediate frequency or radio-frequency signals. For example, transceiver circuitry 28 may include mixer circuitry for up-converting (or modulating) the baseband signals to intermediate frequencies or radio frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may include a transmitter component to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry for downconverting the received radio-frequency signals into corresponding intermediate frequency or baseband signals. For example, transceiver 28 may use sampling circuitry 50 for down-converting (or demodulating) the received radio-frequency signals to baseband frequencies prior to conveying the received signals to processing circuity 26 over path 34. Sampling circuitry 50 that is used down-converting radio-frequency signals is sometimes referred to as a downsampling mixer.

Conventional mixers typically include a phase-locked loop (PLL) to generate a high-frequency clock signal to (de)modulate the radio-frequency (RF) signals. The high-frequency clock signal can have a frequency equal to the frequency of the RF signals. The use of a PLL, however, consumes a significant amount of current and thus might not be suitable for low-power applications such as battery-operated devices. To help reduce the power consumption of mixers, a receiver can sometimes include a single-phase sub-sampling mixer. A “single-phase” subsampling mixer can refer to a mixer having one sampling circuit that is controlled by a single phase of a low-frequency clock signal. The low-frequency clock signal may have a frequency f LOW that is substantially less than the frequency of the RF signals. A single-phase subsampling mixer can, however, produce aliases at multiples of f LOW, which can fold back onto the baseband signal of interest as interference/blocker signals if not properly filtered out.

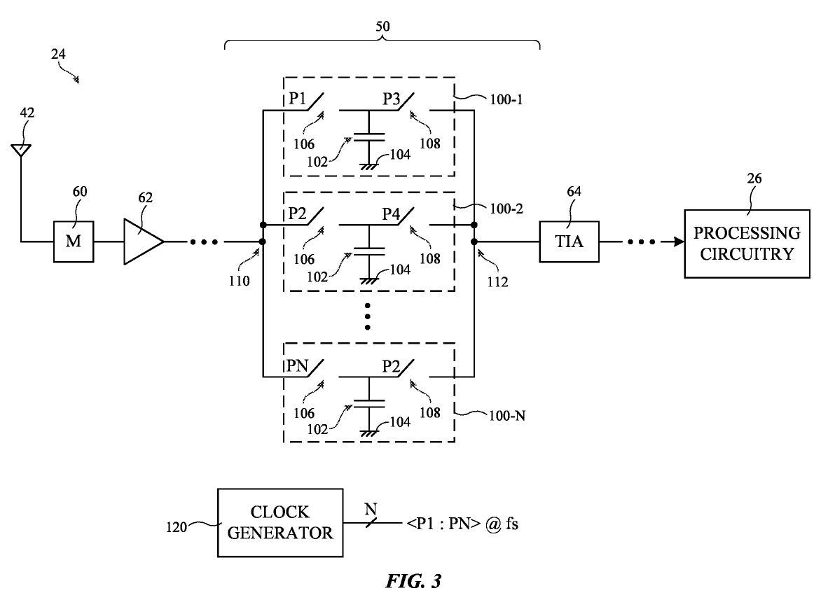

In accordance with an embodiment, FIG. 3 shows a multi-phase subsampling mixer such as multi-phase subsampling mixer circuitry 50 that does not require a PLL while reducing blocker interference. FIG. 3 shows how wireless circuitry 24 can include an antenna 42, an amplifier 62 (e.g., a low noise amplifier in a receive path), a matching circuit 60 coupled between antenna 42 and amplifier 62 and configured to provide impedance matching between antenna 42 and amplifier 62, multi-phase subsampling mixer circuitry 50 coupled to the output of amplifier 62, an additional amplifier such as transimpedance amplifier (TIA) 64 coupled to the output of mixer circuitry 50, and processing circuitry 26 coupled to the output of amplifier 64.

The use of low noise amplifier 62 at the input of mixer circuitry 50 is illustrative and can optionally be omitted. In some embodiments, input 110 of mixer circuitry 50 can be directly connected to antenna 42 or other radio-frequency signal receiving terminal/port. In general, one or more circuit components (e.g., circuits within front-end module 40 shown in FIG. 2 or other radio-frequency components) may be interposed between antenna 42 and mixer circuitry 50. Similarly, the use of transimpedance amplifier 64 at the output of mixer circuitry 50 is also illustrative and can optionally be omitted. If desired, one or more additional circuit components may be interposed between mixer circuitry 50 and processing circuitry 26. Mixer circuitry 50 may be part of a transceiver within wireless circuitry 24. If desired, the transceiver may also include a data conversion circuit such as an analog-to-digital converter (ADC) and/or a digital-to-analog converter (DAC) configured to convert signals between an analog domain and a digital domain. In general, signals interfacing with mixers and/or antennas are in the analog domain, whereas signals interfacing with processing circuitry 26 are in the digital domain.

Multi-phase subsampling mixer circuitry 50 may have a first (input) terminal 110 coupled to antenna 42 and a second (output) terminal 112 coupled to processing circuitry 26. A radio-frequency signal may be received at input terminal (node) 110. Mixer circuitry 50 can thus sometimes be referred to as a radio-frequency mixer. A corresponding downconverted (demodulated) signal can be produced at output terminal (node) 112. Mixer circuitry 50 may include N sampling circuits such as first sampling circuit 100-1, second sampling circuit 100-2, . . . , and N^{th} sampling circuit 100-N. In general, N can be an integer that is greater 2, greater than 5, 5-10, greater than 10, 10-20, 20-50, 50-100, or greater than 100. Each sampling circuit 100 can include a capacitor 102, an input switch 106, and an output switch 108. Capacitor 102 may have a first terminal coupled to a node disposed between switches 106 and 108 and a second terminal coupled to a ground power supply line 104 (e.g., a ground line on which ground power supply Vss is provided). Capacitor 102 having a terminal shorted to ground line 104 is sometimes referred to as a “shunt” capacitor. The input switch 106, sometimes referred to as an input sampling switch, may be coupled between terminal (node) 110 and the first terminal of capacitor 102. The output switch 108 may be coupled between the first terminal of capacitor 102 and terminal (node) 112.

The N sampling circuits 100 may be controlled using clock signals output from a clock generation circuit such as clock generator 120. Clock generator 120 can be configured to output N clock signals of different phases. The first clock signal with a first phase can be referred to as the first clock phase P1; the second clock signal with a second phase that is delayed with respect to the first phase can be referred to as the second clock phase P2; the third clock signal with a third phase that is delayed with respect to the second phase can be referred to as the third clock phase P3; and so on. In other words, clock generator 120 can output N respective clock phases, where each successive clock phase is offset from the previous clock phase by 360°/N. As an example where N is equal to 10, clock generator 120 can output 10 clock phases successively offset by 36°. As another example where N is equal to 20, clock generator 120 can output 20 clock phases successively offset by 18°. These examples are merely illustrative.

Each of the N clock signals (phases) output from clock generator 120 can have a sampling frequency f S that is less than frequency f RF of the incoming radio-frequency signal. For example, sampling frequency f S can be equal to frequency f RF divided by N. Sampling input signals using a relatively lower frequency (e.g., where f S is less than or a fraction of f RF) is a technique that can be referred to and defined herein as “subsampling.” Each sampling circuit 100 can thus sometimes be referred to herein as a subsampling circuit 100 (e.g., a circuit configured to sample an input signal using a sampling frequency that is a fraction of the frequency of the input signal).

Each sampling circuit 100 can be controlled using different clock phases. In the example of FIG. 3, the input switch 106 of sampling circuit 100-1 can be controlled using clock phase P1, whereas the output switch 108 of sampling circuit 100-1 can be controlled using clock phase P3. For sampling circuit 100-2, its input switch 106 can be controlled using clock phase P2 while its output switch 108 can be controlled using clock phase P4. For sampling circuit 100-N, its input switch 106 can be controlled using clock phase PN while its output switch 108 can be controlled using clock phase P2. In this example, controlling the input switch 106 using clock phase i while controlling the corresponding output switch 108 within the same sampling circuit 100 using clock phase (i+2) can help ensure that there is no temporal overlap between the input sampling period when switch 106 is activated and the output period when switch 108 is activated. Such clock phase distribution is exemplary. In general, input switch 106 of a given sampling circuit 100 can be controlled using a certain clock phase while output switch 108 of the same given sampling circuit 100 can be controlled using any one of the remaining clock phases. Controlling the various sampling circuits 100 using different phases of a clock signal is a method of operation that can be referred to and defined herein as “multi-phase” sampling.

The term “activate” with respect to a switch (or transistor) may refer to or be defined herein as an action that places the switch in an “on”or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

The N clock phases can be output using clock generator 120 that is implemented as a delay-locked loop (DLL) such as a multiplying delay-locked loop (MDLL). An MDLL may refer to a particular type of DLL circuit that generates a clock signal having a frequency that is an integer multiple of a reference clock frequency. In particular, clock generator 120 is not a phase-locked loop (PLL). DLLs employ a delay-line to generate one or more clock phases, whereas PLLs use a voltage-controlled oscillator (VCO) to output a high-frequency clock signal. DLLs and PLLs are different types of clock generation circuits. Implementing clock generator 120 as a DLL (e.g., a multiplying DLL) rather than a PLL can help dramatically reduce power consumption since DLLs are less power hungry than PLLs.

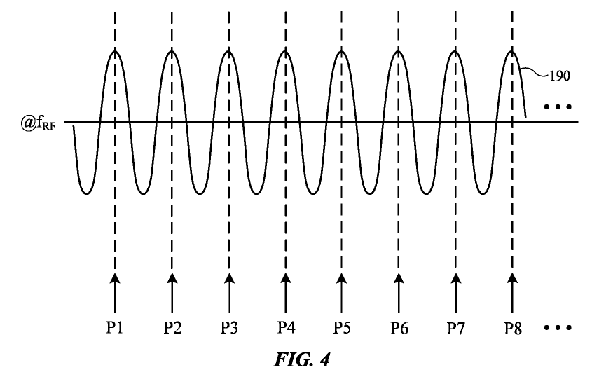

FIG. 4 is a timing diagram illustrating how a radio-frequency signal (see waveform 190) can be subsampled using multiple clock phases output from clock generator 120 in accordance with some embodiments. The radio-frequency waveform 190 can have a radio frequency f RF. As shown in FIG. 4, a first point (e.g., peak) of the RF waveform 190 can be sampled using the first clock phase P1; a second point (e.g., peak) of the RF waveform 190 can be sampled using the second clock phase P2; a third point (e.g., peak) of the RF waveform 190 can be sampled using the second clock phase P3; and so on. Using multiple phases of the same low-frequency clock signal (e.g., clock phases with sampling frequency f S that is a fraction of the radio frequency f RF) to subsample the RF waveform 190 in this way can help ensure that a sufficient number of samples of waveform 190 is acquired even when the sampling frequency f S is muchlower than frequency f RF of the incoming signal being sampled.

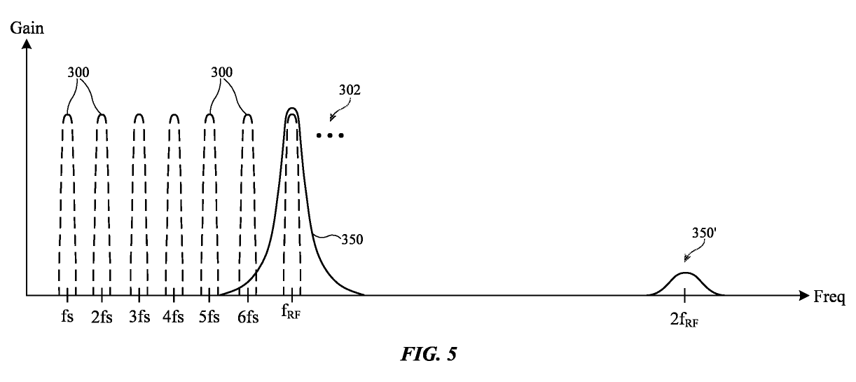

FIG. 5 is a plot of gain versus frequency showing how multi-phase sampling can exhibit improved blocker rejection over single-phase sampling in accordance with some embodiments. The example of FIG. 5 illustrates a scenario where the subsampling frequency f S is equal to f RF divided by seven. Such a scenario where N is equal to 7 is merely illustrative. Here, dotted lines 300 represent gain responses at multiples of f S, sometimes referred to as aliases, when using single-phase subsampling. Although such aliases are shown to stop at frequency f RF in FIG. 5, the aliases can be repeated at frequencies above f RF (as shown by ellipsis 302). These aliases, if not properly filtered, can be downconverted into blocker signals that interfere with the baseband (DC) signal of interest.

In contrast, curve 350 represents the gain response of multi-phase subsampling mixer circuitry 50. Unlike the single-phase subsampling scenario, curve 350 only exhibits signal gain at the desired frequency f RF without producing any unwanted aliases. Multi-phase subsampling mixer circuitry 50 may exhibit a relatively small amount of signal gain at higher multiples of f RF (see, e.g., waveform 350’ at frequency 2*f RF). Regardless, the gain responses 350 and 350’ associated with multi-phase subsampling mixer circuitry 50 exhibit much improved tolerance to signal (blocker) interference without the need to have anti-aliasing filters to reject the unwanted aliases.

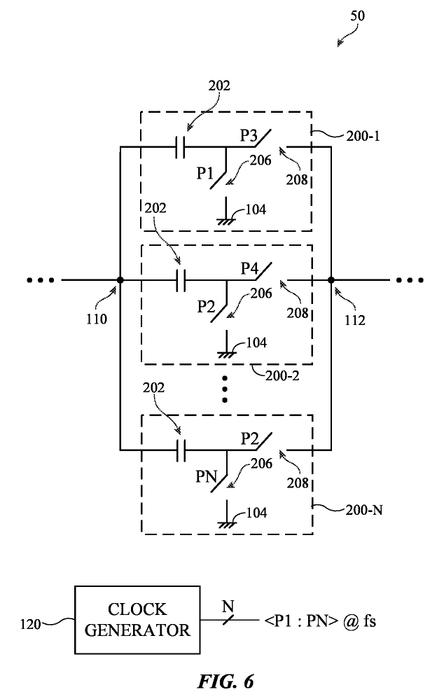

The embodiment of FIG. 3 in which each of the N sampling circuits 100 includes a shunt capacitor 102 and switches 106 and 108 is illustrative. FIG. 6 illustrates another embodiment of multi-phase subsampling mixer circuitry 50 configured to provide signal boosting in accordance with some embodiments.

Multi-phase subsampling mixer circuitry 50 of FIG. 6 may have a first (input) terminal 110 coupled to antenna 42 and a second (output) terminal 112 coupled to processing circuitry 26. Mixer circuitry 50 of FIG. 6 may include N sampling circuits such as first sampling circuit 200-1, second sampling circuit 200-2, . . . , and N^{th} sampling circuit 200-N. In general, N can be an integer that is greater 2, greater than5, 5-10, greater than 10, 10-20, 20-50, 50-100, or greater than 100.

Each sampling circuit 200 can include a capacitor 202, an input switch 206, and an output switch 208. Capacitor 202 may have a first terminal coupled to node 110 and a second terminal. Capacitor 202 arranged in this way is sometimes referred to as a “series” capacitor. The input switch 206, sometimes referred to as an input sampling switch, may be coupled between the second terminal of capacitor 202 and ground power supply line 104 (e.g., a ground line on which ground power supply Vss is provided). The output switch 208 may be coupled between the second terminal of capacitor 202 and terminal (node) 112. A sampling circuit 200 configured in this way with series capacitor 202 can provide voltage doubling capabilities (e.g., to scale the sampled input voltage by a factor of two). Sampling circuit 200 of such type is thus sometimes referred to as a voltage doubler or, more generally, a voltage multiplier.

The N sampling circuits 200 may be controlled using clock signals output from a clock generation circuit such as clock generator 120. Clock generator 120 can be configured to output N clock signals of different phases. The first clock signal with a first phase can be referred to as the first clock phase P1; the second clock signal with a second phase after the first phase can be referred to as the second clock phase P2; the third clock signal with a third phase after the second phase can be referred to as the third clock phase P3; and so on. In other words, clock generator 120 can output N respective clock phases, where each successive clock phase is offset from the previous clock phase by 360°/N.

Each of the N clock signals (phases) output from clock generator 120 can have a sampling frequency f S that is less than frequency f RF of the incoming radio-frequency signal. For example, sampling frequency f S can be equal to frequency f RF divided by N. Each sampling circuit 200 can thus sometimes be referred to herein as a subsampling circuit 200. Each sampling circuit 200 can be controlled using different clock phases. In the example of FIG. 6, the input switch 206 of sampling circuit 200-1 can be controlled using clock phase P1, whereas the output switch 208 of sampling circuit 200-1 can be controlled using clock phase P3. For sampling circuit 200-2, its input switch 206 can be controlled using clock phase P2 while its output switch 208 can be controlled using clock phase P4. For sampling circuit 200-N, its input switch 206 can be controlled using clock phase PN while its output switch 108 can be controlled using clock phase P2. In this example, controlling the input switch 106 using clock phase i while controlling the corresponding output switch 108 within the same sampling circuit 200 using clock phase (i+2) can help ensure that there is no temporal overlap between the input sampling period when switch 206 is activated and the output period when switch 208 is activated. Such clock phase distribution is exemplary. In general, input switch 206 of a given sampling circuit 200 can be controlled using a certain clock phase while output switch 208 of the same given sampling circuit 200 can be controlled using any one of the remaining clock phases.

Clock generator 120 of FIG. 6 can be implemented as a delay-locked loop (DLL) such as a multiplying delay-locked loop (MDLL). In particular, clock generator 120 is not a phase-locked loop (PLL). Implementing clock generator 120 as a DLL (e.g., a multiplying DLL) rather than a PLL can help dramatically reduce power consumption since DLLs are less power hungry than PLLs. The DLL-based clock generator 120 can sometimes be considered part of multi-phase subsampling mixer circuitry 50. The multi-phase subsampling mixer circuitry 50 of FIG. 6 can, in addition to exhibiting lower power consumption and improved blocker rejection characteristics compared to conventional mixers, provide improved noise figure due to the signal multiplying capabilities of sampling circuits 200. In particular, amplifying the sampled input signal within mixer circuitry 50 effectively attenuates the noise of downstream stages in the receiver chain, which enhances the signal-to-noise ratio while minimizing the noise figure of the receiver.

The methods and operations described above in connection with FIGS. 1-6 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 or control circuitry 14 of FIG. 1, etc.). The processing circuitry may include microprocessors, application processors, digital signal processors, central processing units (CPUs), application-specific integrated circuits with processing circuitry, or other processing circuitry.

The foregoing is illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Radio-frequency mixer circuitry comprising:
an input terminal configured to receive a radio-frequency signal;
an output terminal on which a corresponding downconverted signal is produced; and
a plurality of subsampling circuits comprising at least one subsampling circuit coupled between the input terminal and the output terminal.

2. The radio-frequency mixer circuitry of claim 1, further comprising:
a clock generator configured to output a plurality of clock signals for controlling the plurality of subsampling circuits.

3. The radio-frequency mixer circuitry of claim 2, wherein the clock generator comprises a delay-locked loop (DLL).

4. The radio-frequency mixer circuitry of claim 2, wherein the clock generator comprises a multiplying delay-locked loop (MDLL) that is different than a phase-locked loop (PLL).

5. The radio-frequency mixer circuitry of claim 2, wherein the radio-frequency signal has a first frequency, and wherein the plurality of clock signals have a second frequency that is less than the first frequency.

6. The radio-frequency mixer circuitry of claim 5, wherein the second frequency is equal to the first frequency divided by N, and wherein N is equal to a total number of subsampling circuits in the plurality of subsampling circuits.

7. The radio-frequency mixer circuitry of claim 6, wherein the plurality of clock signals are successively offset by a phase equal to 360 degrees divided by N.

8. The radio-frequency mixer circuitry of claim 2, wherein:
a first subsampling circuit in the plurality of subsampling circuits is configured to be controlled by at least a first clock signal of a first phase in the plurality of clock signals; and
a second subsampling circuit in the plurality of subsampling circuits is configured to be controlled by at least a second clock signal of a second phase, different than the first phase, in the plurality of clock signals.

9. The radio-frequency mixer circuitry of claim 2, wherein at least one subsampling circuit in the plurality of subsampling circuits comprises:
a capacitor having a first terminal and a second terminal that is coupled to a power supply line; and
an input switch coupled between the input terminal and the first terminal of the capacitor.

10. The radio-frequency mixer circuitry of claim 9, wherein the at least one subsampling circuit in the plurality of subsampling circuits further comprises:
an output switch coupled between the first terminal of the capacitor and the output terminal, wherein the input switch is configured to be controlled by a first clock signal in the plurality of clock signals and wherein the output switch is configured to be controlled by a second clock signal in the plurality of clock signals.

11. The radio-frequency mixer circuitry of claim 2, wherein at least one subsampling circuit in the plurality of subsampling circuits comprises:
a capacitor having a first terminal coupled to the input terminal and having a second terminal; and
a first switch coupled between the second terminal of the capacitor and a power supply line.

12. The radio-frequency mixer circuitry of claim 11, wherein the at least one subsampling circuit in the plurality of subsampling circuits further comprises:
a second switch coupled between the second terminal of the capacitor and the output terminal, wherein the first switch is configured to be controlled by a first clock signal in the plurality of clock signals and wherein the second switch is configured to be controlled by a second clock signal in the plurality of clock signals.

13. A method of operating a mixer comprising:
with a first sampling circuit, receiving a radio-frequency signal;
with a second sampling circuit coupled in parallel with the first sampling circuit, receiving the radio-frequency signal;
with a first clock phase, controlling the first sampling circuit; and
with a second clock phase that is delayed with respect to the first clock phase, controlling the second sampling circuit.

14. The method of claim 13, further comprising:
with a third sampling circuit coupled in parallel with the first and second sampling circuits, receiving the radio-frequency signal; and
with a third clock phase that is delayed with respect to the second clock phase, controlling the third sampling circuit.

15. The method of claim 13, wherein the radio-frequency signal has a first frequency, and wherein the first and second clock phases each have a second frequency that is a fraction of the first frequency.

16. The method of claim 13, wherein the first sampling circuit comprises:
a shunt capacitor;
an input switch coupled to a terminal of the shunt capacitor and configured to receive the first clock phase; and
an output switch coupled to the terminal of the shunt capacitor and configured to receive a third clock phase different than the first and second clock phases.

17. The method of claim 13, wherein the first sampling circuit comprises:
a series capacitor;
a first switch coupled to a terminal of the series capacitor and configured to receive the first clock phase; and
a second switch coupled to the terminal of the series capacitor and configured to receive a third clock phase different than the first and second clock phases.

18. Mixer circuitry comprising:
an input terminal configured to receive a radio-frequency signal;
an output terminal on which a corresponding downconverted signal is configured to be produced; and
a plurality of sampling circuits coupled in parallel between the input terminal and the output terminal and configured to boost a signal level of the radio-frequency signal.

19. The mixer circuitry of claim 18, wherein:
the radio-frequency signal has a first frequency;
a first sampling circuit in the plurality of sampling circuits is configured to be controlled by a first pair of clock phases having a second frequency that is a fraction of the first frequency;
a second sampling circuit in the plurality of sampling circuits is configured to be controlled by a second pair of clock phases, different than the first pair of clock phases, having the second frequency; and
a third sampling circuit in the plurality of sampling circuits is configured to be controlled by a third pair of clock phases, different than the first and second pairs of clock phases, having the second frequency.

20. The mixer circuitry of claim of claim 18, wherein at least one sampling circuit in the plurality of sampling circuits comprises:
a capacitor having a first terminal coupled to the input terminal;
a first switch having a first terminal coupled to a second terminal of the capacitor and having a second terminal coupled to a ground line; and
a second switch having a first terminal coupled to the second terminal of the capacitor and having a second terminal coupled to the output terminal.
